(19) United States
(12) Patent Application Publication
(10) Pub. No.: US 2015/0257314 A1
(43) Pub. Date: Sep. 10, 2015

(54) COATINGS AND METHODS FOR PROVIDING FABRICS WITH FAUX METAL PLATINGS

(71) Applicant: Laird Technologies, Inc., Earth City, MO (US)

(72) Inventors: Larry Don Creasy, JR., St. Clair, MO (US); Kelly G. Cook, St. Louis, MO (US); Richard Tsai, Xinbei City (TW); Dusan Lee, Shenzhen (CN)

(21) Appl. No.: 14/718,954

(22) Filed: May 21, 2015

Related U.S. Application Data
(63) Continuation of application No. PCT/CN2012/086166, filed on Dec. 7, 2012.

(51) Int. Cl. H05K 9/00; C09D 5/24; D06M 11/83; C08K 3/34; C08K 3/22; D06M 15/564; C09D 175/04; C08K 3/08

(52) U.S. Cl. CPC H05K 9/0092; C09D 175/04; C09D 5/24; C08K 3/08; C08K 3/346; C08K 3/22; D06M 15/564; D06M 11/83; C08K 2003/0893; C08K 2003/0812; C08K 2003/085; C08K 2003/2241; D06M 2101/36

(57) ABSTRACT

According to various aspects, exemplary embodiments are disclosed of coatings and methods for providing faux metal platings and/or aesthetic coloring to fabrics. In an exemplary embodiment, a coating for providing a faux metal plating and/or aesthetic coloring to a fabric generally includes a resin and a powder mixed in the resin. The coating may have a color corresponding to a metal plating such that the coating resembles a metal plating on the fabric after being applied to the fabric.

### CROSS-REFERENCE TO RELATED APPLICATION

This application is a continuation of PCT International application No. PCT/US2012/086166 filed Dec. 7, 2012 (published as WO 2014/086038 on Jun. 12, 2014). The entire disclosure of the above application is incorporated herein by reference.

### FIELD

The present disclosure relates to coatings and methods for providing fabrics with faux metal platings and/or aesthetic coloring.

### BACKGROUND

This section provides background information related to the present disclosure which is not necessarily prior art.

Metal plated fabrics may be used for EMI shielding purposes, such as nickel metal plated fabric from Laird Technologies, Inc. By way of example, Laird's Flectron® metallized fabric may include nickel and copper plated fabric in which nickel is plated over a base layer of copper previously plated on the fabric. In use, the base layer of copper is highly electrically conductive copper while the outer layer of nickel provides corrosion resistance.

### SUMMARY

This section provides a general summary of the disclosure, and is not a comprehensive disclosure of its full scope or all of its features.

According to various aspects, exemplary embodiments are disclosed of coatings and methods for providing faux metal platings and/or aesthetic coloring to fabrics. In an exemplary embodiment, a coating for providing a faux metal plating and/or aesthetic coloring to a fabric generally includes a resin and a powder mixed with the resin. The coating may have a color corresponding to a metal plating such that the coating resembles a metal plating on the fabric after being applied to the fabric.

In an exemplary embodiment of a method of providing a faux metal faux metal plating and/or aesthetic coloring to a fabric, the method generally includes coating a fabric with a coating comprising a resin and a powder mixed in the resin. The coating has a color corresponding to a metal plating such that the coating resembles a metal plating on the fabric.

Also disclosed are methods for making a coating for providing a faux metal plating and/or aesthetic coloring to a fabric. In an exemplary embodiment, a method generally includes mixing a powder in a resin to make a coating having a color corresponding to a metal plating such that the coating resembles a metal plating on a fabric after being applied to the fabric.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a line graph of transfer impedance per ASTM D4935 showing attenuation in decibels (dB) versus frequency in hertz (Hz) for a copper plated nylon ripstop fabric and for a copper plated nylon ripstop fabric with a faux nickel coating applied over the copper plating according to an exemplary embodiment.

FIG. 2 is a line graph of transfer impedance per ASTM D4935 showing attenuation in decibels (dB) versus frequency in hertz (Hz) for two copper plated nylon ripstop fabrics with a faux nickel coating applied over their copper platings according to exemplary embodiments.

FIG. 3 is a line graph of shielding effectiveness in decibels (dB) versus frequency in hertz (Hz) for two copper plated nylon ripstop fabrics with a faux nickel coating applied over their copper plating according to exemplary embodiments.

FIG. 4 is a line graph of abrasion resistance per ASTM D3886 (Modified) showing resistivity in ohms/sq versus cycles for two copper plated nylon ripstop fabrics with a faux silver coating applied over their copper platings according to exemplary embodiments.

### DETAILED DESCRIPTION

Example embodiments will now be described more fully with reference to the accompanying drawings.

As noted above in the background, metal plated fabrics may be used for EMI shielding purposes. While such metal plated fabrics may work well for their intended EMI shielding purposes, the inventors hereof have recognized that it would be beneficial to develop coatings and methods for providing fabrics with faux or imitation metal platings that may be applied to a fabric at lower costs and/or via less complicated processes than traditional metal plating processes. The inventors hereof also recognized that it would be beneficial to develop faux nickel coatings that look like a nickel plating and/or are nickel colored without including any nickel, and thus are nonallergenic and non-irritating to users that are allergic to nickel.

Accordingly, the inventors hereof developed and disclose herein exemplary embodiments of coatings and methods for providing fabrics with faux or imitation metal platings, such as faux nickel, yellow gold, brass, bronze, or silver plating, etc. In exemplary embodiments, a coating may be configured to resemble a metal plating on a fabric after being applied thereto. Thus, the coated fabric may thus look or visually appear to have been plated with one or more metals (e.g., nickel, silver, aluminum, tin, gold, brass, bronze, etc.) even though it was instead coated with a coating disclosed herein. Advantageously, the coating may be applied to the fabric at a lower cost and via a less complicated process than traditional metal plating processes, such as by dipping or immersing the fabric in the coating, by spraying the coating onto the fabric, by using knife over roll and knife over air industrial fabric coaters, by using gap coaters or other roll coating equipment for web applications, etc.

A coating disclosed herein may be configured to have any one of a wide range of colors depending on the particular end use of the coated fabric (e.g., liner for wallet, purse, backpack, laptop bag, EMI shield, etc.). Accordingly, the color of a coating may thus be tailored or customized for the particular end use (e.g., nickel color for a wallet, metallic color for an EMI shield, etc.). By way of example, a coating may be configured such that the coated fabric is colored metallic gray, nickel, silver, black, white, gray, silver white, yellow, copper, among other possible colors, etc. Also for example, a coating may be configured such that the coated fabric has a shiny or glistening metallic appearance or metallic luster, e.g., appearance of nickel, silver, aluminum, tin, gold, brass, bronze, etc. The inventors' coatings may thus allow for a coated fabric to have virtually any color depending on the particular composition (e.g., powder formula, etc.).

In exemplary embodiments, a coating is configured such that the fabric coated therewith will visually appear to have been plated with nickel. In such embodiments, the coating does not include any nickel and thus may be referred to as a faux or imitation nickel coating or plating. The faux nickel coating may be applied directly to a fabric (e.g., polyester taffeta, ripstop, etc.) or to a preexisting coating or plating on the fabric. For example, the faux nickel coating may be applied to a base copper layer previously plated on the fabric. In which case, the faux nickel coating may provide corrosion protection to the base copper layer when coated thereon. After being applied, the faux nickel coating appears or resembles a nickel plating and/or is nickel colored. Because the coating does not include nickel, this imitation or faux nickel coating or plating will thus be nonallergenic and non-irritating to the skin of a user that is allergic to nickel. This means that the object or article including the coated fabric (e.g., wallet, purse, backpack, laptop bag, etc.) may be used without causing an allergic reaction and without irritating the user's skin even if the user is allergic to nickel. This also allows for the elimination of the nickel plating process as it allows for the appearance of a nickel plating via a coating process at a much lower cost and via a much less complicated process than traditional metal plating processes. By way of example only, the fabric coated with a faux nickel coating disclosed herein may have the same or similar color as a nickel metal plated fabric, such as Flectron® metallized fabric or other nickel-plated, copper-plated fabric from Laird Technologies, Inc.

In an exemplary embodiment, a faux nickel coating comprises nickel-colored powder(s) mixed in a resin. The selection of a nickel-colored powder may depend, for example, on particle size, ability of powder to disperse in the resin, and/or desired coating performance, such as good surface resistivity along the fabric's weft and warp. A wide range of non-nickel or nickel free powders may be used in a faux nickel coating, such as aluminum powder, tin powder, zinc powder, combinations thereof, etc.

The resin may comprise a urethane (e.g., polyurethane, etc.) resin. A thickener or thickening agent may also be mixed in the resin. By way of example, the thickening agent may be used to help thicken of the resin so that the resin is not too fluid to provide good coverage (e.g., good coating coverage at the gridding, etc.).

In an exemplary embodiment, a faux nickel coating may be prepared by mixing nickel-colored powder with a urethane based coating in a tank. The faux nickel coating may be applied to a fabric via a knife over roll coated or applicator in a coating line. Then, the coating may be dried, for example, at a drying temperature of 80° C., 85° C., 105° C., 100° C., 120° C., 140° C., 150° C., etc. and a drying time of 30 minutes, etc. Other suitable mixing processes and coating processes may be used in other embodiments depending, for example, on the coating composition and material to be coated.

In an exemplary embodiment, a faux nickel coating is prepared by sequentially adding a pigment, a dispersion agent, a resin, an ammonium solution, and finally a thickening agent into a mixing tank while continuously stirring the mixture in the tank as each material is being added. After all the materials have been added, the mixture in the tank is stirred, e.g., for a further 30 minutes, etc. to help ensure that the mixture in the tank is a homogenous coating solution.

Continuing with this example, about 5 grams to about 25 grams, and preferably about 15 grams, of the pigment is first added or poured into the mixing tank. The pigment preferably comprises a water based mixture of one or more fine powders of aluminum, zinc, tin, copper, clay, titanium oxide, a combination thereof, etc. depending on the desired color or metal that the coating is intended to resemble, e.g., metallic gray, nickel, silver, black, white, gray, silver white, yellow, copper, gold, bronze, brass, tin, aluminum, etc.

Second, about 2 grams to about 30 grams, and preferably about 10 grams, of the dispersion agent is next poured or added to the mixing tank while continuously stirring the mixture in the tank. The dispersion agent preferably comprises a kind of polymer which helps dispersion of pigment in the solution, such as EG/PG copolymer or other suitable dispersion agents.

Third, about 50 grams to about 100 grams, and preferably about 75 grams, of the resin is then poured or added to the mixing tank while continuously stirring the mixture in the tank. The resin preferably comprises a water based polyurethane resin that will firm the pigment and become the film of coating.

Fourth, about 0.2 grams to about 2 grams, and preferably about 1 gram of ammonium hydroxide solution is poured or added to the mixing tank while continuously stirring the mixture in the tank. The ammonium hydroxide solution preferably comprises ammonium (28%) hydroxide solution that will adjust the pH in a range from 8.5 to 10.

Fifth, about 0.1 gram to about 1 grams, and preferably about 0.5 grams of the thickening agent is then poured or added to the mixing tank while continuously stirring the mixture in the tank. The thickening agent is preferably selected so as to adjust viscosity to make the coating suitable for knife coating.

Exemplary embodiments of the coatings disclosed herein may be applied to fabrics by various processes, such as by dipping or immersing the fabric in the coating, by spraying the coating onto the fabric, by using knife over roll and knife over air industrial fabric coaters, by using gap coaters or other roll coating equipment for web applications, etc. By way of example only, a coating may be applied to a fabric as follows. First, the fabric to be coated may be unwound with a tension setting from about 20 to 35 Newtons (e.g., 25.5 Newtons, etc.). The oven temperature settings may be 50° C., 70° C., 70° C., 70° C., and 50° C. for the polyurethane and first silver coats, and 80° C., 100° C., 100° C., and 80° C. for the second silver coat. A polyurethane solution may be used as clear base coating, and silver solution may be coated on both sides to provide a metal appearance. The coating may then be dried, and the coated fabric may be taken up, sampled, and tested.

In some embodiments, multiple coatings are applied to a fabric, for example, to improve the appearance (e.g., color, luster, glistening appearance, etc.) of the coated fabric where the multiple coatings may be applied via the same process described above or a different process. The multiple coatings may all comprise the same coating composition, or they may be different. For example, a fabric may be coated twice with one of the coatings disclosed herein. By way of further example, a fabric may first be coated with a first coating and then coated with a second coating, where the second coating strengthens the yellow gold color such that the coated fabric appears to look like it has been plated with real gold.

As disclosed above, exemplary embodiments are directed to coatings and methods for providing fabrics with faux or imitation metal platings, such as faux nickel, gold, brass, bronze, or silver plating, etc. Example coating formulas, chemical makeup or compositions are provided below for faux or imitation nickel, silver, and yellow gold platings, which may be used in exemplary embodiments. These coating formulas, including the percentages, suppliers and product numbers, are provided only for purposes of illustration and not for purposes of limitation as other coating formulas, percentages, suppliers, etc. may be used in other embodiments.

In an exemplary embodiment, a faux or imitation nickel plating comprises about 5% percent to about 25% (and preferably about 15%) by dry weight of silver-colored powder or pigment (e.g., silver-colored powder product number #2100 from Shenzhen Yuhongtai Technology Co., Ltd., etc.); and about 2% percent to about 30% (and preferably about 10%) by dry weight of dispersion agent (e.g., dispersion agent product number #K56 from DongGuan Keruixia Tech, etc.); and about 50% percent to about 90% (and preferably about 70%) by dry weight of resin (e.g., resin product number #505 from TW Yangsheng Chemicals Inc., etc.); and about 0.2% percent to about 2% (and preferably about 1%) by dry weight of ammonium hydroxide solution; and about 0.1% percent to about 2% (and preferably about 0.5%) by dry weight of thickening agent (e.g., thickening agent product number #GH420 from DongGuan Keruixia Tech, etc.); and about 1% percent to about 5% (and preferably about 2%) by dry weight of yellow-colored powder or pigment (e.g., yellow pigment product number #026 from Shenzhen Yuhongtai Technology Co., Ltd.).

In another exemplary embodiment, a faux or imitation silver plating comprises about 5% percent to about 25% (and preferably about 15%) by dry weight of silver-colored powder or pigment (e.g., silver-colored powder product number #2100 from Shenzhen Yuhongtai Technology Co., Ltd., etc.); and about 2% percent to about 30% (and preferably about 10%) by dry weight of dispersion agent (e.g., dispersion agent product number #K56 from DongGuan Keruixia Tech, etc.); and about 50% percent to about 90% (and preferably about 75%) by dry weight of resin (e.g., resin product number #505 from TW Yangsheng Chemicals Inc., etc.); and about 0.2% percent to about 2% (and preferably about 1%) by dry weight of ammonium hydroxide solution; and about 0.1% percent to about 2% (and preferably about 0.5%) by dry weight of thickening agent (e.g., thickening agent product number #GH420 from DongGuan Keruixia Tech, etc.).

In another exemplary embodiment, a faux or imitation gold plating is provided on a fabric by first applying a first coating and then applying a second coating over the first coating. The second coating strengthens the yellow gold color such that the coated fabric appears to look like it has been plated with real gold. In this example, the first coating comprises about 5% percent to about 25% (and preferably about 15%) by dry weight of silver-colored powder or pigment (e.g., silver-colored powder product number #2100 from Shenzhen Yuhongtai Technology Co., Ltd., etc.); and about 2% percent to about 30% (and preferably about 10%) by dry weight of dispersion agent (e.g., dispersion agent product number #K56 from DongGuan Keruixia Tech, etc.); and about 50% percent to about 90% (and preferably about 70%) by dry weight of resin (e.g., resin product number #505 from TW Yangsheng Chemicals Inc., etc.); and about 0.2% percent to about 2% (and preferably about 1%) by dry weight of ammonium hydroxide solution; and about 0.1% percent to about 2% (and preferably about 0.5%) by dry weight of thickening agent (e.g., thickening agent product number #GH420 from DongGuan Keruixia Tech, etc.); and about 5% percent to about 15% (and preferably about 10%) by dry weight of yellow-colored powder or pigment (e.g., yellow pigment product number #026 from Shenzhen Yuhongtai Technology Co., Ltd.). Continuing with this example, the second coating comprises about 85% percent to about 95% (and preferably about 90%) by dry weight of resin (e.g., resin product number #505 from TW Yangsheng Chemicals Inc., etc.); and about 0.2% percent to about 2% (and preferably about 1%) by dry weight of ammonium hydroxide solution; and about 0.1% percent to about 2% (and preferably about 0.5%) by dry weight of thickening agent (e.g., thickening agent product number #GH420 from DongGuan Keruixia Tech, etc.); and about 5% percent to about 10% (and preferably about 5%) by dry weight of yellow-colored powder or pigment (e.g., yellow pigment product number #026 from Shenzhen Yuhongtai Technology Co., Ltd.).

In exemplary embodiments, a coating may be configured to resemble a metal plating on a fabric after being applied thereto. Thus, the coated fabric may thus look or visually appear to have been plated with one or more metals (e.g., nickel, silver, aluminum, tin, gold, brass, bronze, etc.) even though it was instead coated with a coating disclosed herein. Advantageously, the coating may be applied to the fabric at a lower cost and via a less complicated process than traditional metal plating processes, such as by dipping or immersing the fabric in the coating, by spraying the coating onto the fabric, by using knife over roll and knife over air industrial fabric coaters, by using gap coaters or other roll coating equipment for web applications, etc.

A wide range of materials and substrates may be coated with a coating disclosed herein, including woven fabrics, non-woven fabrics, fabrics woven on one side and non-woven on the other side, meshes, materials having a preexisting or prior plating or coating thereon, other substrates, etc. By way of example, coatings disclosed herein may be applied to polyester woven or non-woven fabrics, polyester taffeta, polyester taffeta laminates, polyester meshes, nylon ripstop (NRS) fabrics or laminates, other ripstop fabrics or laminates, preexisting plating or coating already applied to a substrate, etc.

In exemplary embodiments, a coated fabric (e.g., fabric coated with an imitation or faux nickel coating/plating, etc.) may be used to make a wallet or portion of a wallet, carrying case, carrier, purse, backpack, laptop bag, suitcase, etc. By way of example, a coated fabric may provide a liner, layer, sleeve, etc. that prevents, protects, or inhibits data on a card (e.g., a magnetic strip on a ticket, a door key, a smart card, etc.) from being erased when in close proximity to a mobile phone, a magnet, etc. Additionally, or alternatively, a coated fabric may be a radio frequency (RF) blocking fabric for use as a liner, layer, sleeve, etc. to provide protection against unauthorized access to data on a card to guard against identity theft, e.g., by preventing unauthorized access to data on an embedded microchip in a credit card by a radio frequency identification (RFID) reader or sensor.

The disclosed exemplary embodiments of coatings and fabrics coated therewith may be used in a wide range of applications, articles, objects, etc. In exemplary embodiments, the coated fabrics may have the flexibility, conformability, and breathability of a woven or non-woven fabric with electrical shielding properties of a metal, low surface resistivity, low Z-axis through resistivity, and excellent shielding effectiveness. In exemplary embodiments, a coated fabric may be packaged in a continuous roll that may be readily cut to fit without special tooling.

In exemplary embodiments, a coating may be applied to a fabric for use as an aesthetically colored EMI fabric. The aesthetically colored EMI fabric may be used as the outer electrically-conductive layer of a fabric-over-foam EMI shielding gasket. The aesthetically colored EMI fabric may also be used as a shielding material in a tape, laminate, an architectural shielding product to shield a complete room, etc. The aesthetic coloring provided via the coating does not interfere with the functionality of the surface conductivity and EMI/RFI shielding effectiveness. In such examples, the coated fabric may provide aesthetic coloring to an EMI shield via the coating being aesthetically colored, e.g., so as to color coordinate (e.g., match the color of, contrast with the color of, etc.) with the color of an adjacent external structure of an electronic equipment housing. The aesthetically colored fabric or portion thereof may be visible external to the electronic equipment housing when the EMI shield is operatively engaged with the electronic equipment housing.

The composition of a particular coating may depend on and/or be tailored to obtain a desired coating performance (e.g., EMI shielding performance, surface resistivity, Z-axis resistivity, electrical conductivity, wet-wash friction test, crockmeter adhesion test, etc.). By way of example only, exemplary embodiments may include the following coating weights: polyurethane coated 6 grams per square meter (g/sm) +/−2 g/sm, one-sided silver coated 8 g/sm +/−2, and two-sided silver coated 8 g/sm +/−2. By way of further example, the specifications for a particular use or application for an exemplary embodiment of the inventors' coated fabric may require a resistivity of less than 0.07 ohms/square as determined by using a four point probe according to 4-Point Sheet Resistivity—ASTM F390 testing procedures, loss on drying (% volatiles) of less than 5%; Z-axis resistance of less than 0.03 ohms, dry crockmeter adhesion test greater than 3 grade, (e.g., more than 4.0 as determined by using a crockmeter according to Adhesion-Modified Crockmeter Method—AATCC TM8 testing procedures); dry-friction test greater than 3 grade, wet-friction test greater than 3 grade, release of nickel test result of not detected, halogen free as defined in the industry (e.g., no more than a maximum of 900 parts per million chlorine, no more than a maximum of 900 parts per million bromine, and no more than a maximum of 1,500 parts per million total halogens), surface resistance of less than 1 ohm/square following 500 cycles of abrasion per the Flexing and Abrasion Method—ASTM D3885 (Modified) testing procedures; and/or abrasion resistance greater than one million cycles as determined according to Abrasion-Inflated Diaphragm Method—ASTM D3886 (Modified) testing procedures; and/or satisfactory shielding effectiveness as determined according to Shielding Effectiveness—IEEE-299 or MIL-STD-83528C testing procedures.

By way of background, the 4-Point Sheet Resistivity—ASTM F390 includes using a special four point probe that is put on a rectangular piece of fabric. The surface resistivity is measured and reported as the quotient of the resistance, measured along the length of fabric, divided by the length (I) to the width (w) ratio. The ratio l/w is the number of squares. Based on the probe configuration, a fabric width of 1 inch results in a quotient of length to width of one, leaving the denominator in the units of “square”. If we measure fabrics not one inch in width, then correction factors are used to adjust the reported value. The surface resistivity in the XY direction should be in units of “ohms/square”.

For Adhesion-Modified Crockmeter Method—AATCC TM8, this test measures the adhesion of the plated metal to the fabric after abrasion. For this test, a Crockmeter with a 0.95 centimeter diameter acrylic finger is moved repeatedly across a piece of 3M “Scotch” brand tape placed over the fabric sample. The tape is then removed from the sample, placed on a white background, and compared to an Adhesion Scale. The fabric is given an adhesion rating of 1 to 5, with 5 representing no metal adhering to the tape.

For Flexing and Abrasion Method—ASTM D3885 (Modified), this test measures the abrasion resistance of metallized fabrics by subjecting one inch wide specimens to unidirectional reciprocal folding and rubbing over a 1.6 millimeter thick bar (knife-edge). The surface resistivity of the fabric is checked with the 4-point probe after 500 cycles.

For Abrasion-Inflated Diaphragm Method—ASTM D3886 (Modified), this test measures abrasion resistance of fabrics. A strip of fabric four inches long and one inch wide is placed in the inflated diaphragm tester. A strip of cotton duck fabric is rubbed on this fabric bi-directionally (no rotation). A one kilogram weight is placed on the top of the unit for pressure and the air pressure of the diaphragm is set to 2.5 pounds per square inch. Therefore, the area of contact is about one inch squared. The surface resistivity is checked periodically at known cycle counts.

For Shielding Effectiveness—IEEE-299 or MIL-STD-83528C, this test measures the shielding level of fabric though a wide range of frequencies. A specimen fabric having dimensions of 0.7 meter×0.7 meter is bolted to cover a 0.6 meter×0.6 meter port in a steel wall of a fully shielding room. A transmitting antenna is placed 3.05 meters outside the port. The receiving antenna is placed an equal distance inside the chamber. The shielding effectiveness of the material is calculated by the difference between the signal strength with and without the specimen in the port. This method can provide both swept frequency and discrete data for electric field, magnetic field, and far field from 100 kilohertz (kHz) to 18 gigahertz (GHz).

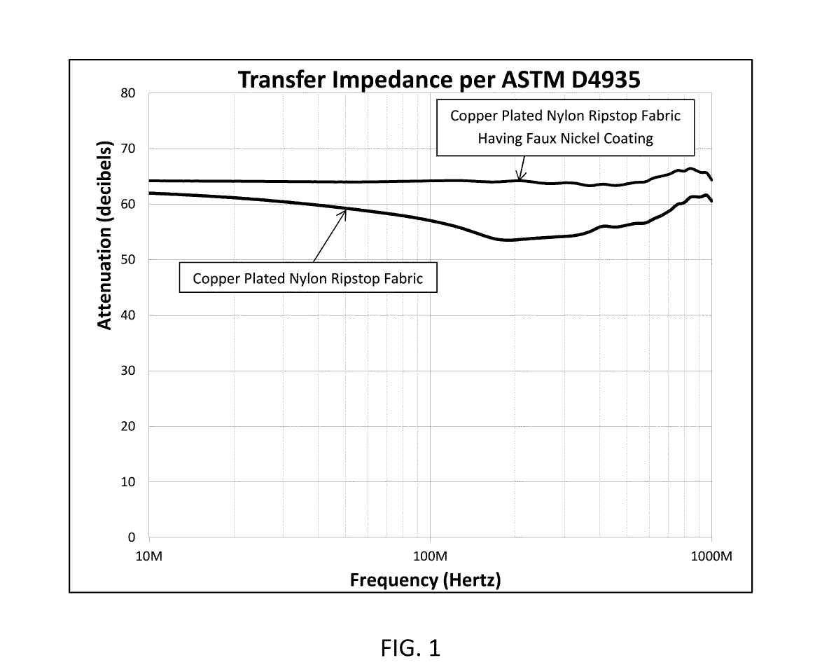

FIGS. 1 through 3 provide analysis results measured for copper plated nylon ripstop fabrics with faux nickel coatings applied over their copper platings as disclosed herein. These analysis results shown in FIGS. 1 through 3 are provided only for purposes of illustration and not for purposes of limitation.

More specifically, FIG. 1 is a line graph of transfer impedance per ASTM D4935 showing attenuation in decibels (dB) versus frequency in hertz (Hz) for a copper plated nylon ripstop fabric having a faux nickel coating applied over the copper plating according to an exemplary embodiment. For comparison purposes, FIG. 1 also shows the transfer impedance for a copper plated nylon ripstop fabric. As shown by FIG. 1, the copper plated nylon ripstop fabric having the faux nickel coating applied over the copper plating performed better than the nylon ripstop fabric coated only with copper. FIG. 1 also shows that the copper plated nylon ripstop fabric having the faux nickel coating applied over the copper plating provided good or satisfactory attenuation of about 65 decibels or more between the frequencies of 10 MHz and 1000 MHz.

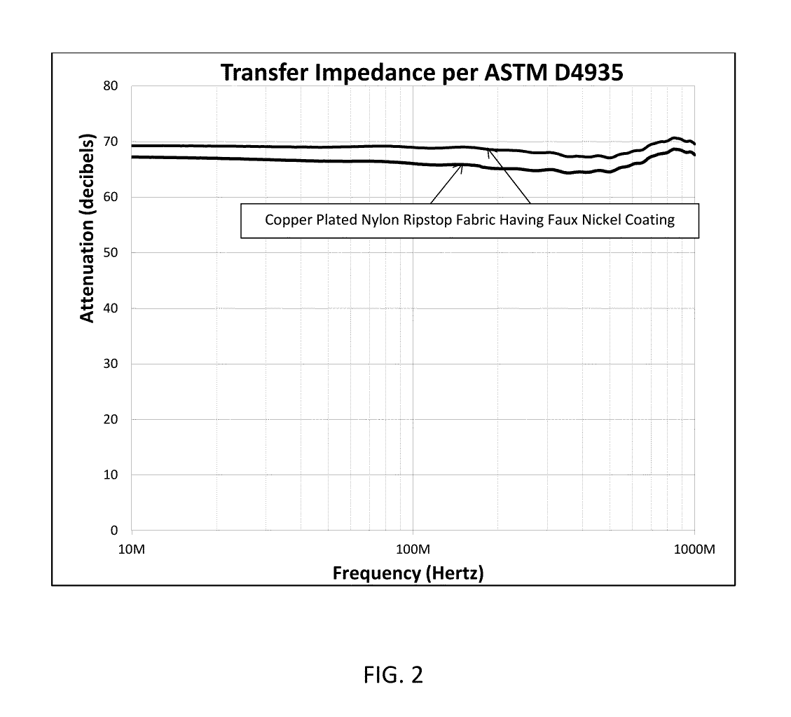

FIG. 2 is a line graph of transfer impedance per ASTM D4935 showing attenuation in decibels (dB) versus frequency in hertz (Hz) for two copper plated nylon ripstop fabrics with a faux nickel coating applied over their copper plating according to exemplary embodiments. As shown by FIG. 2, these test specimens provided good or satisfactory attenuation of about 65 decibels or more between the frequencies of 10 MHz and 1000 MHz.

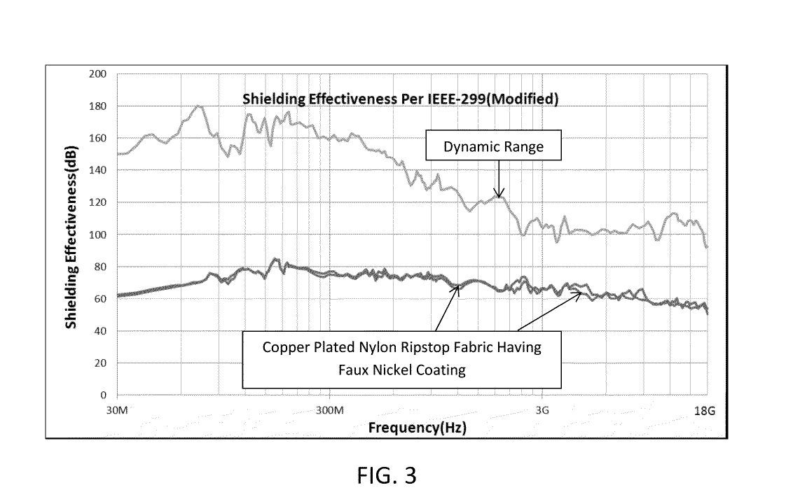

FIG. 3 is a line graph of shielding effectiveness in decibels (dB) versus frequency in hertz (Hz) for two copper plated nylon ripstop fabrics with a faux nickel coating applied over their copper plating according to exemplary embodiments. As shown by FIG. 3, these test specimens had good or satisfactory shielding effectiveness of more than 50 decibels between the frequencies of 30 MHz and 18 Gigahertz (GHz).

The data shown in FIG. 3 was obtained via radiating shielding effective testing, which was performed in accordance to IEEE-299 (modified) as described below. Generally, the test set-up or configuration included a 24 inch×24 inch brass common aperture between two separate galvanized steel shielded enclosures. The width of the brass surface was 1 inch. The test specimen or electrically conductive fabric sheet was clamped to the test fixture by four 24 inch aluminum mounting rails. Testing was performed over the frequency range of 30 MHz to 18 GHz. Bi-conical antennas were used for testing from 30 MHz to 200 MHz, and double ridge waveguide antennas were used for testing from 30 MHz to 18 GHz. The antennas were located on each side of the test fixture, the distance from the antennas to the sample is 750 millimeters (mm) (for 30 MHz to 200 MHz test), 600 mm (for 200M Hz to 1 GHz test), and 700 mm (for 1 GHz to 18 GHz test). Each antenna was in an individually shielded enclosure. Mode stirring was employed in the transmitting room to homogenize the electromagnetic wave. Reference readings were taken through the test fixture aperture. The test sample was installed in the test fixture. Readings were taken in the same frequency range as for the reference readings. The difference in the signal amplitude through the open aperture compared to the amplitude of the signal through the test sample is the shielding effectiveness (attenuation) of the test sample.

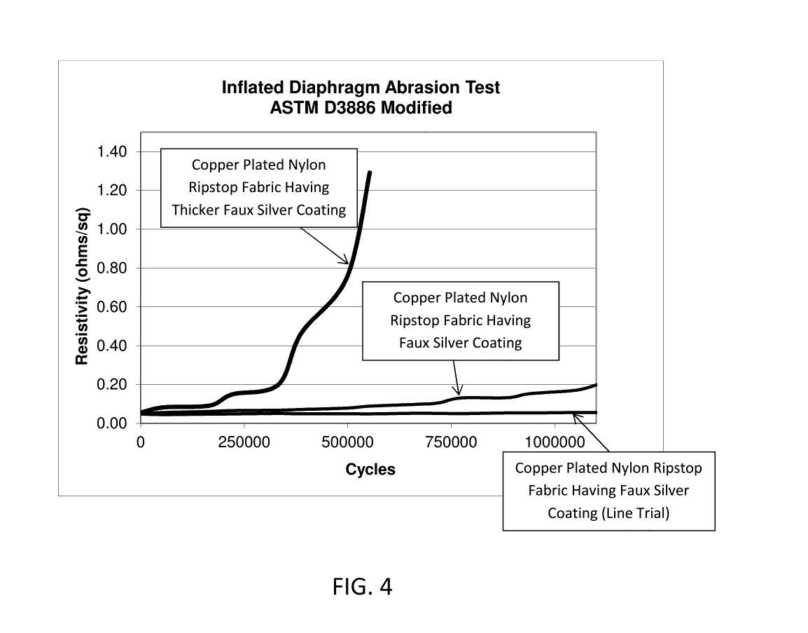

FIG. 4 provides analysis results measured for copper plated nylon ripstop fabrics with faux silver coatings applied over their copper platings as disclosed herein. Again, these analysis results shown in FIG. 4 are provided only for purposes of illustration and not for purposes of limitation.

More specifically, FIG. 4 is a line graph of abrasion resistance per ASTM D3886 (Modified) showing resistivity in ohms/sq versus cycles for copper plated nylon ripstop fabrics with faux silver coatings applied over their copper platings according to exemplary embodiments. The table below provides the data plotted in the line graph of FIG. 4. The first and second columns include results for two lab samples created during product development, while the third column (designated Line Trial) includes results for a sample from a production run. The coating thickness of the test samples was between about 5 grams per square meter to about 12 grams per square meter where the coatings were applied by a knife coating process. As shown by a comparison of columns 1 and 2, the lab sample with the thinner coating (column 2) had better test results than the lab sample (column 1) with the thicker coating, which had higher Z-axis resistivity.

Inflated Diaphragm Abrasion Test

| Modified ASTM D3886 | | | |
|---|---|---|---|
| | Silver Colored | Silver Colored | Silver Colored |
| | Coating Over | Coating Over | Coating over |
| | Copper Plated | Copper Plated | Copper Plated |
| Cycles | NRS | NRS | NRS (Line Trial) |
| 0 | 0.0561 | 0.0499 | 0.0479 |
| 55000 | 0.0824 | 0.0559 | 0.0453 |
| 166000 | 0.0917 | 0.0614 | 0.0475 |
| 221000 | 0.1493 | 0.0659 | 0.0484 |
| 332000 | 0.1991 | 0.0677 | 0.0510 |
| 387000 | 0.4625 | 0.0714 | 0.0491 |
| 498000 | 0.7521 | 0.0787 | 0.0499 |
| 553000 | 1.2916 | 0.0885 | 0.0488 |
| 664000 | | 0.0978 | 0.0521 |
| 719000 | | 0.1052 | 0.0514 |
| 774000 | | 0.1308 | 0.0504 |
| 885000 | | 0.1321 | 0.0538 |
| 940000 | | 0.1528 | 0.0537 |
| 1051000 | | 0.1707 | 0.0558 |
| 1106000 | | 0.2013 | 0.0557 |

Additional tables are provided below that includes further analysis results measured for various test specimens where each test specimen included copper plated nylon ripstop fabric (NRS) with either a silver colored coating or yellow gold colored coating applied over the base copper plating as disclosed herein. As before, these analysis are also provided only for purposes of illustration and not for purposes of limitation. In addition, the columns designated with (Line Trial) include results for samples from production runs. The columns designated with BTA include results for samples with BTA (Benzotriazole, which is an organic copper corrosion inhibitor) in the coating. After testing samples with and without BTA, the inventors hereof realized that BTA was not necessary or required as the samples without BTA did not experience any corrosion issues.

| | Silver Colored | Silver Colored | Silver Colored |
|---|---|---|---|
| | Coating over | Coating over | Coating over |
| | Copper Plated | Copper Plated | Copper Plated |
| | NRS | NRS | NRS (Line Trial) |
| Thickness | 0.004 | 0.0043 | 0.0046 |
| (inches) | | | |
| Total Weight | 4.60 | 2.47 | 2.56 |
| (opsy) | | | |
| Surface Resistivity | 0.0858 | 0.0434 | 0.0458 |
| ASTM F390 | | | |
| (ohms/square) | | | |
| Abrasion | 4.2380 | 0.3691 | 0.3912 |
| ASTM D3885 | | | |
| (Ω/sq @ | | | |
| 500 cycles) | | | |
| Abrasion | <600,000 | >1,00,000 | >1,000,000 |
| ASTM D3886 | | | |
| (# of cycles) | | | |
| Crockmeter | 2.5 | 5 | 5 |
| Adhesion (1-5) | | | |
| Fray Test | >1 mm | 0 mm | 0 mm |
| (mm of frayed end) | | | |
| Corrosion with | 0.1143 | 0.0509 | |
| Zinc? | | | |
| (40° C./90% RH | | | |
| for 72 hours) | | | |
| after 1 week | 0.1234 | 0.0524 | |
| after 2 weeks | 0.1257 | 0.0569 | |
| after 3 weeks | | 0.0581 | |
| after 4 weeks | | 0.0579 | |
| after 5 weeks | | 0.0619 | |
| after 6 weeks | | 0.0626 | |
| Corrosion with | | 0.0491 | |
| Brass? | | | |
| (40° C./90% RH | | | |
| for 72 hours) | | | |
| after 1 week | | 0.0558 | |
| after 2 weeks | | 0.0522 | |
| after 3 weeks | | 0.0534 | |
| after 4 weeks | | 0.0524 | |
| after 5 weeks | | 0.0525 | |
| after 6 weeks | | 0.0562 | |

| | | Silver Colored | Gold Colored |
|---|---|---|---|
| | Silver Colored | Coating over | Coating over |
| | Coating over | Copper Plating | Copper Plating |
| | Copper Plating | with BTA | with BTA |
| | with BTA | (Line Trial) | (Line Trial) |
| Thickness | 0.0045 | 0.0047 | 0.0049 |
| (inches) | | | |
| Total Weight | 2.50 | 2.74 | 3.03 |
| (opsy) | | | |
| Surface Resistivity | 0.1648 | 0.0738 | 0.0708 |
| ASTM F390 | | | |
| (ohms/square) | | | |
| Abrasion ASTM | 2.036 | 0.6873 | 0.4230 |
| D3885 (Ω/sq | | | |
| @ 500 cycles) | | | |
| Crockmeter | 5 | 5 | 5 |
| Adhesion (1-5) | | | |
| Fray Test | 0 mm | 0 mm | 0 mm |
| (mm of frayed end) | | | |
| Corrosion with Zinc? | | 0.0967 | 0.0592 |
| (40° C./90% RH | | | |
| for 72 hours) | | | |
| Corrosion with Brass? | | 0.0656 | 0.0747 |
| (40° C./90% RH | | | |
| for 72 hours) | | | |

ASTM D3885 (Modified) Abrasion Test

| | Silver Colored | Silver Colored | Silver Colored | |
|---|---|---|---|---|
| | Coating over | Coating over | Coating over | |
| | Copper Plated | Copper Plated | Copper Plated | Average |
| Cycles | BTA1 | BTA2 | BTA3 | ohms/sq |
| 0 | 0.1161 | 0.0318 | 0.3466 | 0.1648 |
| 500 | 2.481 | 0.4047 | 3.221 | 2.0356 |

ASTM D3885 (Modified) Abrasion Test

| | Silver Colored | Silver Colored | Silver Colored | |
|---|---|---|---|---|
| | Coating over | Coating over | Coating over | |
| | Copper Plated | Copper Plated | Copper Plated | Average |
| Cycles | NRS | NRS | NRS | ohms/sq |
| 0 | 0.0562 | 0.0707 | 0.0946 | 0.0738 |
| 500 | 0.3896 | 0.5302 | 1.1421 | 0.6873 |

ASTM D3885 (Modified) Abrasion Test

| | Silver Colored | Silver Colored | Silver Colored | |
|---|---|---|---|---|
| | Coating over | Coating over | Coating over | |
| | Copper Plated | Copper Plated | Copper Plated | |
| | NRS | NRS | NRS | Average |
| Cycles | (Line Trial 1) | (Line Trial 2) | (Line Trial 3) | ohms/sq |
| 0 | 0.0445 | 0.0476 | 0.0452 | 0.0458 |
| 500 | 0.2654 | 0.5719 | 0.3362 | 0.3912 |

ASTM D3885 (Modified) Abrasion Test

| | Gold Colored | Gold Colored | Gold Colored | |
|---|---|---|---|---|
| | Coating over | Coating over | Coating over | |
| | Copper Plated | Copper Plated | Copper Plated | Average |
| Cycles | NRS | NRS | NRS | ohms/sq |
| 0 | 0.0689 | 0.0823 | 0.0613 | 0.0708 |
| 500 | 0.2865 | 0.3951 | 0.5873 | 0.4230 |

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances. Or for example, the term “about” as used herein when modifying a quantity of an ingredient or reactant of the invention or employed refers to variation in the numerical quantity that can happen through typical measuring and handling procedures used, for example, when making concentrates or solutions in the real world through inadvertent error in these procedures; through differences in the manufacture, source, or purity of the ingredients employed to make the compositions or carry out the methods; and the like. The term “about” also encompasses amounts that differ due to different equilibrium conditions for a composition resulting from a particular initial mixture. Whether or not modified by the term “about”, the claims include equivalents to the quantities.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A coating for providing a faux metal plating and/or aesthetic coloring to a fabric that is usable as an EMI shielding material, the coating comprising:
a resin; and
a powder mixed with the resin;
whereby the coating has a color corresponding to a metal plating such that the coating resembles a metal plating on the fabric after being applied to the fabric.

2. The coating of claim 1, wherein:
the resin comprises a urethane resin;
the powder comprises one or more of aluminum, zinc, and/or tin;
the coating does not include nickel such that the coating is nonallergenic and non-irritating to a user allergic to nickel; and
the coating after being applied to a fabric resembles a nickel plating on the fabric.

3. The coating of claim 1, wherein:
the resin comprises a urethane resin;
the coating comprises:
a pigment that is a water based mixture that includes the powder;
a thickening agent to adjust viscosity of the coating; and
a dispersion agent to help disperse the pigment.

4. The coating of claim 3, wherein:
the powder comprises one or more of aluminum, zinc, tin, copper, clay, and/or titanium oxide;
the dispersion agent comprises a polymer dispersion agent;
the coating includes ammonium hydroxide for adjusting pH; and
the urethane resin comprises a water based urethane resin to help firm the pigment.

5. The coating of claim 1, wherein:
the powder comprises a nickel-colored powder such that the coating is nickel colored without requiring nickel, whereby the coating after being applied to a fabric resembles a nickel plating on the fabric; and
the coating does not include nickel such that the coating is nonallergenic and non-irritating to a user allergic to nickel.

6. The coating of claim 1, wherein the powder comprises a colored powder that is configured so that the coating after being applied to a fabric resembles a gold, silver, nickel, brass, or bronze plating on the fabric.

7. The coating of claim 1, wherein the coating has:
no more than a maximum of 900 parts per million chlorine, no more than a maximum of 900 parts per million bromine, and no more than a maximum of 1,500 parts per million total halogens; and/or
a surface resistivity of less than 0.07 ohms/square; and/or
a Z-axis resistance of less than 0.03 ohms.

8. The coating of claim 1, wherein:
the coating comprises about 5 grams to about 25 grams of pigment; about 2 grams to about 30 grams of dispersion agent; about 50 grams to about 100 grams of resin; about 0.2 grams to about 2 grams of ammonium hydroxide; and about 0.1 gram to about 1 grams of thickening agent; or
the coating comprises about 5% percent to about 25% by dry weight of silver-colored powder; about 2% percent to about 30% by dry weight of dispersion agent; about 50% percent to about 90% by dry weight of resin; about 0.2% percent to about 2% by dry weight of ammonium hydroxide solution; about 0.1% percent to about 2% by dry weight of thickening agent; and about 1% percent to about 5% by dry weight of yellow-colored powder or pigment; or
the coating comprises about 5% percent to about 25% by dry weight of silver-colored powder; about 2% percent to about 30% by dry weight of dispersion agent; about 50% percent to about 90% by dry weight of resin; about 0.2% percent to about 2% by dry weight of ammonium hydroxide solution; and about 0.1% percent to about 2% by dry weight of thickening agent.

9. The coating of claim 1, wherein the coating comprises:
a first coating comprising about 5% percent to about 25% by dry weight of silver-colored powder; about 2% percent to about 30% by dry weight of dispersion agent; about 50% percent to about 90% by dry weight of resin; about 0.2% percent to about 2% by dry weight of ammonium hydroxide solution; about 0.1% percent to about 2% by dry weight of thickening agent; and about 5% percent to about 15% by dry weight of yellow-colored powder or pigment; and
a second coating comprising about 85% percent to about 95% by dry weight of resin; about 0.2% percent to about 2% by dry weight of ammonium hydroxide solution; about 0.1% percent to about 2% by dry weight of thickening agent; and about 5% percent to about 10% by dry weight of yellow-colored powder.

10. An EMI shielding material comprising a fabric aesthetically colored by the coating of claim 1.

11. An article including a fabric aesthetically colored by the coating of claim 1, wherein:
the article comprises one or more of a wallet, a purse, a backpack, and a laptop bag; and/or
the fabric comprises a woven fabric, a non-woven fabric, and/or nylon ripstop fabric; and/or
the fabric having the coating thereon is colored black, silver, white, yellow, or gray.

12. A faux nickel coating comprising:
a urethane resin; and
a powder mixed with the resin and comprising one or more of aluminum, zinc, and/or tin;
whereby the coating does not include nickel such that the coating is nonallergenic and non-irritating to a user allergic to nickel; and
whereby the coating after being applied to a fabric resembles a nickel plating on the fabric which is usable as an EMI shielding material.

13. The faux nickel coating of claim 1, wherein the coating comprises:
a pigment that is a water based mixture that includes the powder;
a thickening agent to adjust viscosity of the coating;
a dispersion agent to help disperse the pigment; and
ammonium hydroxide for adjusting pH.

14. An EMI shielding material comprising a fabric including the faux nickel coating of claim 11.

15. A method of providing a faux metal plating and/or aesthetic coloring for a fabric usable as an EMI shielding material, the method comprising:
mixing a powder with a resin to make a coating having a color corresponding to a metal plating such that the coating resembles a metal plating on a fabric after being applied to the fabric; and/or
coating a fabric with a coating that comprises a resin and a powder mixed with the resin, wherein the coating has a color corresponding to a metal plating such that the coating resembles a metal plating on the fabric.

16. The method of claim 15, wherein the method comprises mixing the powder with the resin to make the coating, and then coating the fabric with the coating.

17. The method of claim 15, wherein mixing the powder with the resin to make the coating comprises mixing a pigment that comprises a water based mixture of colored powder with a polymer dispersion agent, a water based urethane resin, ammonium hydroxide, and a thickening agent.

18. The method of claim 15, wherein:
the powder comprises a nickel-colored powder such that the coating is nickel colored without requiring nickel, whereby the coating after being applied to a fabric resembles a nickel plating on the fabric; and/or
the coating does not include nickel such that the coating is nonallergenic and non-irritating to a user allergic to nickel.

19. The method of claim 15, wherein:
the resin comprises a urethane resin;
the powder comprises one or more of aluminum, zinc, tin, copper, clay, and/or titanium oxide; and
the coating comprises:
a pigment that is a water based mixture that includes the powder;
a thickening agent to adjust viscosity of the coating;
a dispersion agent to help disperse the pigment; and
ammonium hydroxide for adjusting pH.

20. The method of claim 19, wherein the method comprises mixing in a tank, while continuously stirring:
about 5 grams to about 25 grams of the pigment;
about 2 grams to about 30 grams of the dispersion agent;
about 50 grams to about 100 grams of the urethane resin;
about 0.2 grams to about 2 grams of the ammonium hydroxide; and
about 0.1 gram to about 1 grams of the thickening agent.
